(19) United States
(12) Patent Application Publication
(10) Pub. No.: US 2014/0053868 A1
(43) Pub. Date: Feb. 27, 2014

(54) Method And Apparatus For Surface Cleaning

(71) Applicants: Abbas Rastegar, Schenectady, NY (US); Arun John Kadaksham, Troy, NY (US)

(72) Inventors: Abbas Rastegar, Schenectady, NY (US); Arun John Kadaksham, Troy, NY (US)

(73) Assignee: Sematech, Inc., Albany, NY (US)

(21) Appl. No.: 13/592,276

(22) Filed: Aug. 22, 2012

(51) Int. Cl. H01L 21/02; B08B 3/12

(52) U.S. Cl. CPC H01L 21/02057; B08B 3/12
USPC 134/1.3; 134/184

(57) ABSTRACT

Embodiments of the present disclosure relate to methods and apparatus for reduction of particle defects from a semiconductor surface, such as for example the reduction of sub 100 micron defects. Methods and apparatus of the present disclosure are particularly useful in the manufacture of semiconductor devices when employing extreme ultraviolet photolithography. In some embodiments, a fluid stream is provided through a nozzle at conditions such that cavitation bubbles are formed, the cavitation bubbles being present in a stable cavitation state or regime. The fluid stream is flowed over at least a portion of the surface. A shockwave is generated or created in the fluid stream. The shockwave momentarily increases acoustic pressure in the fluid causing the cavitation bubbles to collapse and produce a jet or pulse of high fluid flow which removes particle defects from the surface.

### TECHNICAL FIELD

The present disclosure relates generally to the cleaning of surfaces such as may be used in the manufacture of semiconductors. More specifically, embodiments of the present disclosure relate to methods and apparatus for reduction of particle defects on a surface, such as but not limited to a semiconductor surface.

### BACKGROUND

In the manufacture of semiconductor devices, reduction of defects, such as particles on the surface of the semiconductor device, is critical. As device densities and sizes continue to decrease, removal of particles from the surface of the device becomes more difficult. Removal of sub-100 nanometer particles from a surface is particularly challenging.

A number of techniques for removal of particles have been explored. One such technique is the use of fluid flow across the surface to removal particles. However, creating the large flow of fluid needed to remove particles close to a surface is very difficult. Due to liquid-surface interactions, the velocity of a fluid at the surface is close to zero, and the fluid velocity will typically reach the bulk velocity some distance from the surface, generally at the boundary layer. Thus, this approach is not very effective at removing particles.

To address this limitation, acoustic cavitation has been explored as a possible method for cleaning a surface, the theory being that implosion of cavitation bubbles close to a surface will provide a jet flow of fluid across the surface at a velocity sufficient to dislodge particles. Depending upon the acoustic pressure and radius of cavitation bubbles produced, different cavitation events will occur.

Two types of cavitation states can be created: transient and stable cavitation. In transient cavitation, a cavitation bubble will grow with an increase in the acoustic field pressure until the bubble will eventually collapse. In stable cavitation, a cavitation bubble will increase to a maximum value as the acoustic field is increased, and will reduce to a minimum value as the acoustic field is decreased. In the instance of stable cavitation, the cavitation bubbles will oscillate between the two sizes and will not collapse.

While cavitation has been explored as a potential mechanism for cleaning a surface, limitations remain. Stable cavitation has not been used in the prior art since its particle removal capability is limited. Transient cavitation has been used in the prior art, but the process is not well controlled. For example when insufficient cavitation energy is present, it is difficult to achieve effective fluid flow such that particles are dislodged from a surface, and process time is slow. However, excessive cavitation energy will cause significant damage to the surface. Thus, further developments are greatly needed.

### SUMMARY

Broadly, the present disclosure relates to removal of defects on the surface of a semiconductor device, such as a wafer or substrate. Methods and apparatus of the present disclosure are particularly useful in the manufacturing of semiconductor devices when employing extreme ultraviolet photolithography.

The inventors have discovered that in a fluid, a state of stable cavitation can be created, and a shock wave can be applied to momentarily increase acoustic pressure and cause all of the stable cavitation bubbles to simultaneously collapse. This simultaneous collapse of all stable cavitation bubbles creates a jet flow of fluid at the surface which is effective at dislodging particles, including sub 100 size nm particles, from the surface of the semiconductor wafer or substrate.

Of particular advantage, methods and apparatus of the present disclosure can be operated in two distinct states, and for illustration purposes can be thought of similar to the operation of a laser. The cavitation states can be thought of as electronic states in a laser, where during the state of stable cavitation, cavities of certain size will oscillate with an acoustic field (can be thought of as populating excited states in a laser). An applied shock wave will collapse all of the stable cavitation bubbles, leading to high coherent fluid flow (can be thought of as the discharge state in a laser) and removal of particle defects from the surface.

In one aspect, a method of reducing contaminant particle defects on the surface of a semiconductor wafer or substrate is provided, comprising creating stable cavitation bubbles in a fluid, and applying a shock wave to the fluid to momentarily increase acoustic pressure and cause all the stable cavitation bubbles to substantially simultaneously collapse, wherein collapse of all the stable cavitation bubbles creates a pulse or jet flow of fluid at the surface which removes particles from the surface. In some embodiments, the shock wave is generated by focusing light onto the fluid to create a shock wave in the fluid by discharge or arc methods.

As described further below, in some embodiments the stable cavitation bubbles have a bubble radius R, and the stable cavitation regime is maintained by providing cavitation bubbles where R>R₁, wherein R₁ is an inertial radius of a bubble. In some embodiments the cavitation bubbles are maintained in the stable cavitation regime by applying acoustic energy to the fluid stream at an acoustic pressure P, and maintaining P<P_{T}, wherein P_{T} is a transient pressure threshold.

The bubble size distribution of the stable cavitation bubbles in the fluid may be controlled. In some embodiments, control of the bubble size distribution is achieved by gasification or degasification of the fluid.

In another aspect, a method of removing particle defects on a surface is provided wherein a fluid is flowed through a nozzle at conditions such that cavitation bubbles are formed in the fluid, and the cavitation bubbles are present in a stable cavitation state. The fluid is flowed over at least a portion of the surface to be cleaned. A shockwave is generated in the fluid at conditions such that the cavitation bubbles collapse substantially simultaneously and produce a pulse of high fluid flow at the surface which removes particle defects from the surface.

In another aspect, an apparatus for removing particle defects from a surface is provided. The apparatus generally includes a support for supporting a surface, a fluid delivery device for delivering a fluid to the surface, and a shockwave generation device. The fluid delivery device may be comprised of a nozzle configured to produce a fluid stream having cavitation bubbles and where the cavitation bubbles are maintained in a stable cavitation state or regime in the fluid stream. The shockwave generation device may be comprised of a light source, such as a laser, and configured to produce a momentary shock wave in the fluid stream. In some embodiments that shockwave generation devices may be comprised of a discharged device. In some embodiments, the apparatus may include a megasonic transducer and a laser shock device where the laser shock device uses discharge or arc methods to create the shockwave in the fluid stream.

### BRIEF DESCRIPTION OF THE DRAWINGS

The foregoing and other aspects of the present disclosure will be apparent upon consideration of the following detailed description, taken in conjunction with the accompanying drawings, in which like reference characters refer to like parts throughout, and in which:

FIGS. 1A and 1B are schematic representations of a fluid in a stable cavitation state showing stable cavitation bubble oscillation with an acoustic field, and an exemplary spatial distribution in time t₁ of cavitation bubbles, respectively;

FIGS. 2A to 2D are schematic representations illustrating application of a shockwave to the stable cavitation bubbles, and their subsequent collapse and fluid flow over a surface, according to embodiments of the present disclosure;

FIG. 3 is a flowchart of an exemplary method according to some embodiments of the present invention; and

FIG. 4 is a simplified side view an apparatus useful for practicing the method of the present disclosure according to some embodiments.

### DETAILED DESCRIPTION OF EXEMPLARY EMBODIMENTS

Example embodiments are described herein in the context of methods and apparatus for minimizing or removing particle defects on a surface, such as for example and without limitation the surface of a semiconductor wafer or substrate, solar cell surface, display surface, and the like. Those of ordinary skill in the art will realize that the following description is illustrative only and is not intended to be in any way limiting. Other embodiments will readily suggest themselves to such skilled persons having the benefit of this disclosure. Reference will now be made in detail to various implementations of the example embodiments as illustrated in the accompanying drawings. The same reference indicators will be used to the extent possible throughout the drawings and the following description to refer to the same or like items.

In the interest of clarity, not all of the routine features of the various implementations disclosed herein are shown and described. It will be appreciated that in the development of any such actual implementation, numerous implementation-specific decisions must be made in order to achieve the developer's specific goals, such as compliance with application- and business-related constraints, and that these specific goals will vary from one implementation to another and from one developer to another. Moreover, it will be appreciated that such a development effort might be complex and time-consuming, but would nevertheless be a routine undertaking of engineering for those of ordinary skill in the art having the benefit of this disclosure.

In this description, the use of the singular includes the plural unless specifically stated otherwise. Also, the use of “or” means “and/or” unless stated otherwise. Similarly, “comprise,” “comprises,” “comprising,” “include,” “includes” “including” “has” and “having” are not intended to be limiting.

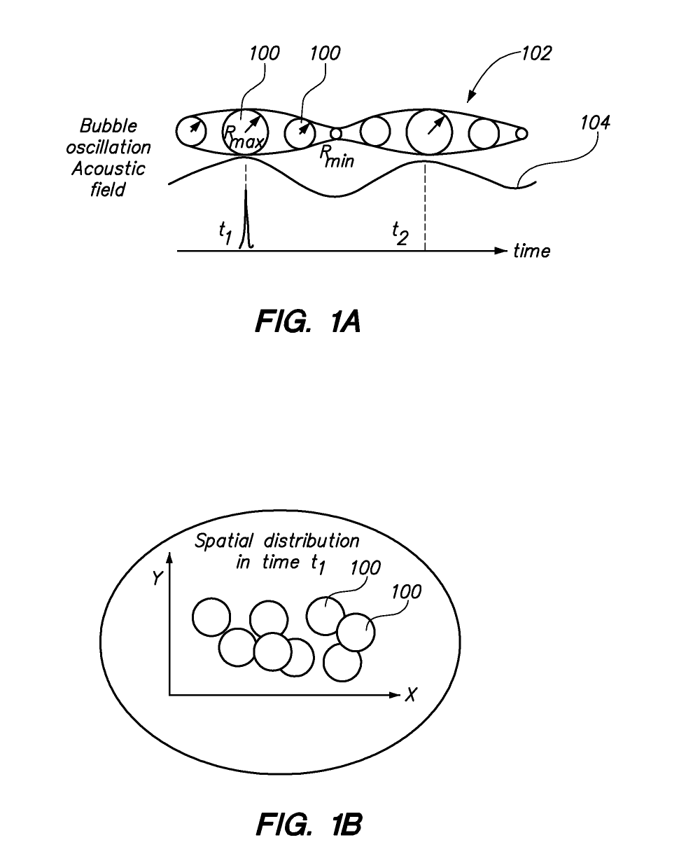

FIGS. 1A and 1B are schematic representations of a stable cavitation state showing stable cavitation bubble oscillation with an acoustic field, and an exemplary spatial distribution in time t₁ of cavitation bubbles. As shown, bubbles 100 in a fluid stream 102 will oscillate between a maximum radius (Rₘₐₓ) and a minimum radius (Rₘᵢₙ) as an acoustic field 104 oscillates. The physics of acoustic cavitation is well studied (see for example “Cavitation” by F. Ronald Young, Imperial college press-1999, ISBN 1-86094-198-2). Cavitation type and formation is determined by initial bubble size and acoustic pressure through a phase diagram chart. To operate in the stable cavitation regime and avoid transient cavitation, the following parameters are applied: For a given ambient pressure (P₀) and frequency (ω) a bubble will become transient only if the radius of the initial bubble (R₀) at the beginning of the acoustic sine wave, is greater than a threshold radius (R_{T}). For a given frequency (ω), a bubble of radius R₀ will grow transient only if the acoustic pressure amplitude (P_{A}) is greater than the threshold pressure (P_{T}). For transient cavitation to occur, bubble radius R₀ must be less than the inertial radius (R₁). Thus, to operate in the stable cavitation regime according to methods of the present invention, acoustic pressure is limited to be below the transient pressure threshold P_{T}, and the bubble radius is kept above R₁. In some embodiments, R is in the range of: 0.1 micron <R<100 micron.

The frequency of the acoustic field is not limited so long as the stable cavitation regime or state is achieved. Methods of the present disclosure may be carried out with acoustic fields in the ultrasonic or megasonic spectrum ranges. In some embodiments, the frequency (ω) is in the megasonic range of about 0.5 MHz to about 5.0 MHz, and more typically in the range of about 0.5 MHz to about 3.0 MHz.

In general analytical calculation of the bubble size is a tedious task, however, at the resonance frequency the relation between bubble size and acoustic field frequency is given by a simple relation [Rᵣₑₛ(μm)=3.28/(ωᵣₑₛ(MHz))] which indicates that by increasing acoustic field frequency the resonance bubble size reduces.

In one exemplary embodiment, bubble size R₁ is determined as follows. This example is provided for illustration purposes only and is not meant to limit the present invention in any way:

for a frequency of 1 MHz and P_{A}=2 P₀, then R₁=2.5 microns,

for a frequency of 1 MHz and P_{A}=20 P₀, then R₁=10.89 microns,

assume P_{A}=20 P₀ for an example megasonic nozzle,

using a frequency of 3 MHz and P_{A}=20 P₀, then R₁=3.63 microns.

To maintain the bubble size at a radius greater than R₁ in the fluid stream, bubble size and distribution can be measured by know light scattering techniques. Alternatively, bubbles size and distribution may be determined from peaks of an FFT signal of the acoustic field, since measured frequencies smaller than the applied frequency implies that the bubbles are larger than the resonant size, and measured frequencies larger than the applied frequency implies that the bubbles are smaller than the resonant size. Once bubble size is known, the distribution of the bubble size may be maintained within the desired parameters by controlling gasification or degasification of the fluid stream. Degasification will reduce the probability that a cavitation happens while high concentration of dissolved gas during regasification will result in so called cushioning effect in which acoustic field propagation will reduce by scattering from too much cavitation bubble in the medium. In addition Pyroelectric coefficient of the dissolved gas is very important in cavitation formation. Gases with high pyroelectric coefficients are more likely to lead to cavitation. For example, in some embodiments gas is flowed through the fluid stream using a bubbler or other suitable device, such as a device with porous membrane, at a flow rate in the range of about 1 l/min to 30 l/min.

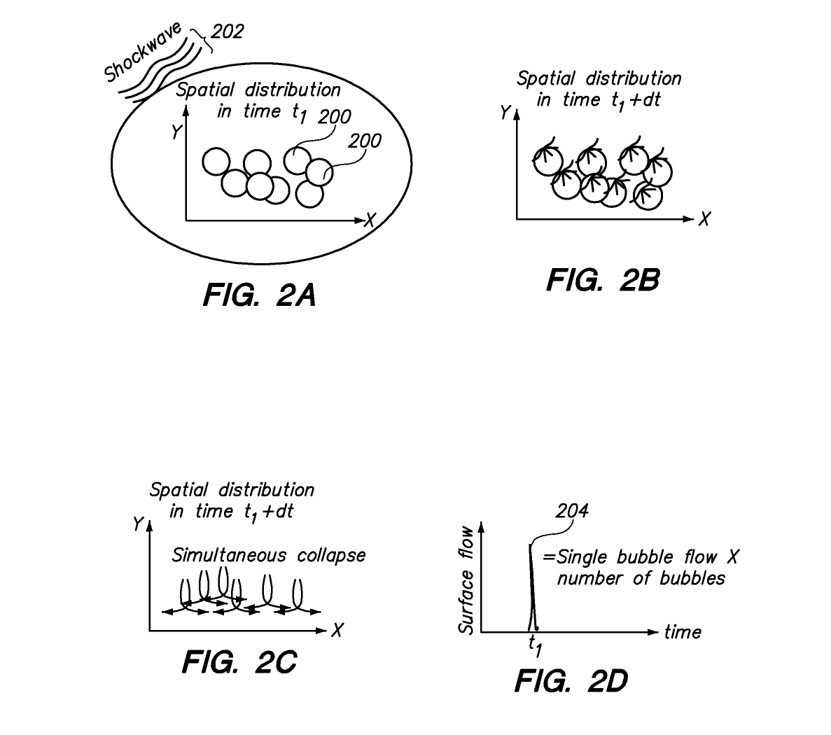

FIGS. 2A to 2D schematically illustrate one embodiment of the method of the present disclosure. A spatial distribution in time t₁ of bubbles 200 in the stable cavitation regime or state are shown as a function of X-Y coordinates in FIG. 2A. A shockwave 202 is applied to the bubbles and impacts the bubbles at time t₁+dt as shown in FIG. 2B. Impact by the shockwave 202 causes substantially simultaneous collapse of the bubbles 200 as illustrated in FIG. 2C, which causes a jet or pulse 204 of fluid flow at t₁ along the surface as shown in FIG. 2D. The sudden jet or pulse 204 of fluid flow dislodges particles from the surface, thereby minimizing or removing defects on the surface of the substrate.

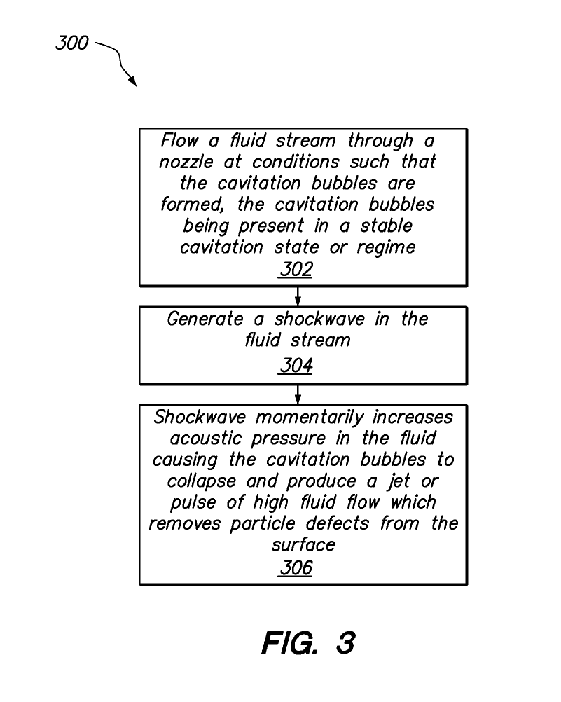

A flowchart depicting one embodiment of the method of the present disclosure is shown in FIG. 3. In this example, a method 300 of removing particle defects from a surface of a semiconductor is described. At step 302, a fluid stream is provided through a nozzle at conditions such that the cavitation bubbles are formed, the cavitation bubbles being present in a stable cavitation state or regime. The fluid stream is flowed over at least a portion of the surface. A shockwave is generated or created in the fluid stream and applied to the cavitation bubbles at step 304. The shockwave momentarily increases acoustic pressure in the fluid causing the cavitation bubbles to collapse at step 306 and produce a jet or pulse of high fluid flow which removes particle defects from the surface.

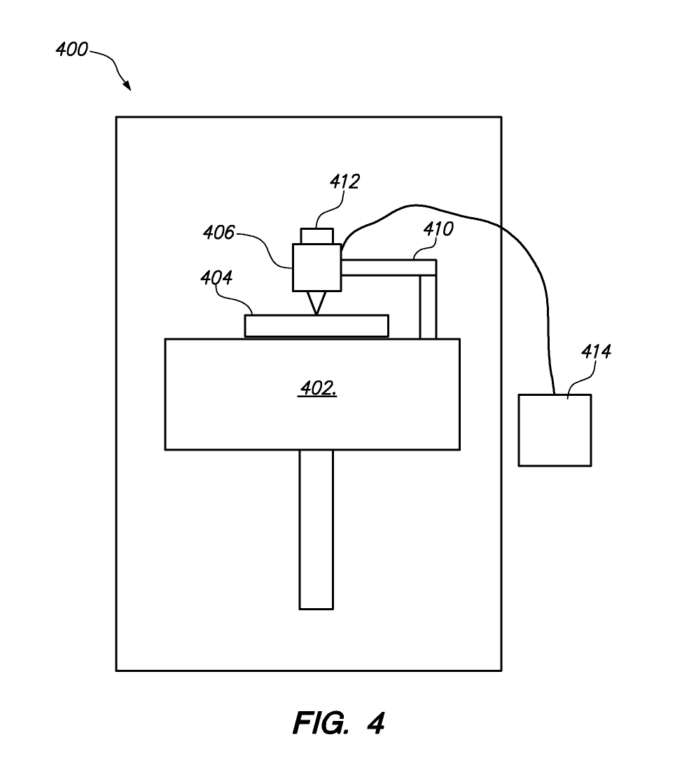

In some embodiments, an apparatus is provided for minimizing particle defects on a surface. Broadly, the apparatus is comprised of a support for supporting a surface, a fluid delivery device, such as a nozzle, for delivering a fluid to the surface, and a shockwave generation device. FIG. 4 shows a simplified side view of one example of an apparatus 400 useful for carrying out the method of the present disclosure. In one exemplary implementation, apparatus 400 is shown and further described in detail in U.S. Pat. No. 7,629,556, the entire disclosure of which is incorporated herein by reference. While one specific apparatus implementation is shown, it should be understood that other systems and configurations are possible within the spirit and scope of the present invention. For example, methods of the present invention can be practiced with an ultrasonic or megasonic transducer system with the addition of a mechanism to generate a shockwave, such as but not limited to a laser shock device which is operated to produce a discharge or arc. Pressure sensors may be used to verify that a shockwave has been generated in the fluid. Shock waves also can be generated by electrical discharge between two electrode in the vicinity of the surface

Referring again to FIG. 4, apparatus 400 generally includes a holder such as a substrate holder 402 for supporting a wafer or substrate 404, and a nozzle 406 typically disposed above the substrate 404, all of which may be enclosed in a housing 408. A light source, such as a laser 414, may be coupled to the nozzle 406.

The substrate 404 may be any semiconductor substrate, such as without limitation: silicon wafer, glass, photovoltaic substrate, compound semiconductor wafer, metalized wafer, and the like, and all of the foregoing may be patterned or unpatterned, a photomask substrate, mask, or any other surface that contains particle defects thereon.

The substrate holder 402 may be comprised of any suitable holder or support, such as a chuck. Typically, the substrate holder 402 is configured to rotate about a central axis. Additionally, the substrate holder 402 may move up and down vertically along a z-axis.

In some embodiments the nozzle 406 is configured to move across the entire or partial surface of the substrate 404. In this instance the nozzle 406 may be coupled to a motor (not shown) via arm 410, which moves the nozzle 406 in any desirable manner over the surface of the substrate in order to remove particle defects at any location on the substrate 404. A source of fluid or fluid feed (not shown) may be coupled to the nozzle 406 to provide one or more fluids to be dispensed by the nozzle 406. Any suitable nozzle that can be operated to provide fluid flow with stable cavitation bubbles may be used. In some embodiments, nozzle 406 is as described in U.S. Pat. No. 7,629,556 (the “'556 patent”), including for example (but not limited to) the nozzle including an integrated light source and being coupled to a megasonic transducer as shown and described in FIG. 11 of the '556, the entire disclosure of which is hereby incorporated by reference.

To create bubble cavitation in the fluid, a source of acoustic energy is provided. In some embodiments, a transducer 412, such as a megasonic transducer, is coupled to the nozzle 406. The transducer 412 generates an acoustic field that at a certain amplitude will induce cavitation in the fluid. As described above, to operate in the stable cavitation regime, the acoustic pressure is limited to be below the transient pressure threshold P_{T}, and the bubble radius is kept above R₁.

It should be understood that any suitable fluid may be used, and that one or more fluids may be combined. Examples of suitable fluids include any one or more of: water, deinoized water, hydrogenated water, ozonated water, ammonia, acids, and mixtures thereof. In some embodiments a mixture of fluids may be used such as ammonia hydroxide/hydrogen peroxide/water.

To provide cleaning of the surface, the fluid is flowed over the surface. Fluid is flowed through the nozzle 406, and an acoustic wave is applied typically by a transducer 412 such as a megasonic transducer, at conditions such that stable cavitation is achieved as illustrated in FIG. 1A and FIG. 1B. Once stable cavitation bubbles are present, a shockwave is applied causing substantially simultaneous collapse of the bubbles and dislodging of particles from the surface of the substrate 404. Thus, the device is operated or modulated between two different states depending on the acoustic energy delivered. One state achieves stable bubble cavitation, and the other state causes substantially simultaneous collapse of the bubbles.

The externally applied shockwave may be produced by any suitable mechanism, such as by discharge or arc methods. In one example, a shockwave is produced by a laser shock device such as described in detail in the '556 patent, which is incorporated herein. In some embodiments the laser shock device is integrated into the nozzle. In some embodiments, the laser shock device is comprised of a laser diode integrated into the arm of the laser shock device, thus forming a single part. In one example, a shockwave may be created within the fluid stream dispensed by the nozzle 406 by focusing laser light 414 onto the fluid stream where the laser has an intensity above a breakdown field of the environment within the nozzle 406. In some embodiments, the laser intensity is in the range of about 100 to 2200 mJ/cm². In one example, the laser intensity is about 300 mJ/cm² or greater to create a shockwave in a fluid when the fluid is DI water .

The foregoing methods and description are intended to be illustrative and are not intended to limit the disclosure in any way. While certain embodiments and applications have been shown and described, it may be apparent to those skilled in the art having the benefit of this disclosure and the teachings provided herein, that other modifications or approaches are possible without departing from the inventive concepts disclosed herein. The invention, therefore, is not to be restricted.

We claim:

1. A method of removing contaminant particle defects from a surface, comprising:
creating cavitation bubbles in a fluid; and
applying a shock wave to the fluid to momentarily increase acoustic pressure and cause all the cavitation bubbles to substantially simultaneously collapse, wherein collapse of all the cavitation bubbles creates a pulse flow of fluid at the surface which removes particles from the surface.

2. The method of claim 1 wherein the cavitation bubbles have a bubble radius R, and the step of creating cavitation bubbles in a fluid further comprises maintaining the relationship: R>R₁,
where R₁ is an inertial radius of a bubble.

3. The method of claim 1 wherein the step of creating cavitation bubbles in a fluid further comprises applying acoustic energy to the fluid stream at an acoustic pressure P, and maintaining the relationship: P<P_{T},
wherein P_{T} is a transient pressure threshold.

4. The method of claim 2 wherein R₁=3.63 microns, when P=20P₀ and frequency=3 MHz, wherein P₀ is the ambient pressure.

5. The method of claim 2 wherein R₁=10.89 microns, when P=20P₀ and frequency=1 MHz, wherein P₀ is the ambient pressure.

6. The method of claim 2 wherein R₁=2.5 microns, when P=2P₀ and frequency=1 MHz, wherein P₀ is the ambient pressure.

7. The method of claim 1 further comprising:
controlling bubble size distribution of the stable cavitation bubbles in the fluid.

8. The method of claim 7 wherein controlling the bubble size distribution is achieved by gasification or degasification of the fluid stream.

9. The method of claim 1 further comprising, generating the shock wave by focusing light onto the fluid to create a plasma and shock wave in the fluid

10. The method of claim 2 wherein R is in the range of: 0.1 micron<R<100 micron.

11. A method of removing particle defects on a surface, comprising:
flowing a fluid through a nozzle at conditions such that cavitation bubbles are formed in the fluid, the cavitation bubbles being present in a stable cavitation state, and where the fluid is flowed over at least a portion of the surface; and
generating a shockwave in the fluid at conditions such that the cavitation bubbles collapse substantially simultaneously and produce a pulse of high fluid flow at the surface which removes particle defects from the surface.

12. An apparatus for removing particle defects from a surface, comprising:
a holder configured to support the surface,
a fluid delivery device configured to deliver a fluid stream having cavitation bubbles to at least a portion of the surface; and
a shockwave generation device configured to produce a momentary shock wave in the fluid stream.

13. The apparatus of claim 12 wherein the fluid delivery device is comprised of a nozzle.

14. The apparatus of claim 12 wherein the shockwave generation device is comprised of a laser.

15. The apparatus of claim 12 wherein the shockwave generation device is comprised of a discharged device.

16. The apparatus of claim 12 wherein the fluid delivery device is coupled to a transducer.

17. The apparatus of claim 16 wherein the transducer is a megasonic transducer.

18. The apparatus of claim 12 wherein the shockwave generation device is comprised of a light source configured to generate plasma and a shock wave within the fluid stream.

19. The apparatus of claim 12 further comprising a bubbler or device with porous membrane, coupled to the fluid delivery device and configured to gasify or degasify the fluid stream.

20. The apparatus of claim 12 wherein the fluid delivery device is a megasonic nozzle and the shockwave generation device is a laser shock device.

21. The apparatus of claim 12 wherein the fluid delivery device is movable to one or more locations on the surface.

22. The apparatus of claim 20 wherein the laser shock device is integrated into the nozzle.

23. The apparatus of claim 20 wherein the laser shock device is comprised of a laser diode integrated into an arm of the fluid delivery device.
